(19) United States
(12) Patent Application Publication
(10) Pub. No.: US 2026/0299444 A1
(43) Pub. Date: Oct. 1, 2026

(54) System and Process for Imprinting

(71) Applicant: Morphotonics Holding B.V., Veldhoven (NL)

(72) Inventors: Rob Antonius Waltherus Neelen, Veldhoven (NL); Jan Matthijs Ter Meulen, Veldhoven (NL)

(21) Appl. No.: 19/480,468

(22) PCT Filed: May 6, 2024
(86) PCT No.: PCT/NL2024/050230

§ 371 Date: Oct. 31, 2025

(30) Foreign Application Priority Data
May 8, 2023 (NL) 2034771

(51) Int. Cl. G03F 9/00; G03F 7/00

(52) U.S. Cl. CPC G03F 9/7042; G03F 7/0002

(57) ABSTRACT

The invention relates to a system for imprinting, in particular nanoimprinting, including at least one substantially flexible stamp configured for imprinting, in particular nanoimprinting, at least one roller configured for exerting pressure onto at least one substantially flexible stamp and/or at least one substrate which is to be imprinted and at least one stage configured for providing support to at least one substrate during imprinting. At least one roller and at least one stage are mutually displaceable in at least an imprint direction in particular such that imprinting is facilitated and wherein the system includes at least one connector which is configured to improve the alignment before and during imprinting.

### CROSS-REFERENCE TO RELATED APPLICATIONS

This application is the United States national phase of International Patent Application No. PCT/NL2024/050230 filed May 6, 2024, and claims priority to The Netherlands Patent Application No. 2034771 filed May 8, 2023, the disclosures of which are hereby incorporated by reference in their entireties.

### BACKGROUND OF THE INVENTION

### Field of the Invention

The invention relates to a system for imprinting, in particular nanoimprinting. The invention also relates to a process for imprinting, in particular nanoimprinting.

### Description of Related Art

Imprinting, and in particular nanoimprinting, requires for certain applications very accurate aligning between the stamp used for imprinting and the substrate which is to be imprinted. However, due to the relatively small structures, which can range for example from 500 micrometer down to 25 nanometer, the alignment requires a high level of accuracy. In conventional roll-to-plate imprinting processes, typically, the substrate which is to be imprinted is aligned with respect to a stage upon which the substrate is positioned during the imprinting process. The stage can also be provided with alignment markers and/or a receiving space wherein the substrate can be received. The known systems have the drawback that the alignment step can be rather time consuming and/or sensitive for aligning errors and damaging of the substrate.

### SUMMARY OF THE INVENTION

Hence, it is a goal of the invention to provide a system and process for imprinting, in particular nanoimprinting wherein the alignment required for the imprinting is improved.

The invention provides thereto a system for imprinting, in particular nanoimprinting, comprising:
preferably at least one substantially flexible stamp configured for imprinting, in particular nanoimprinting;
at least one roller configured for exerting pressure onto at least one substantially flexible stamp and/or at least one substrate which is to be imprinted;
at least one stage configured for providing support to at least one substrate during imprinting;
   wherein at least one roller and at least one stage are mutually displaceable in at least an imprint direction in particular such that imprinting is facilitated; and wherein the system comprises:
at least one connector which is attached or attachable to at least part of the substantially flexible stamp and/or to at least part of the stage in particular such that the relative position of the flexible stamp and the stage is constant.

The system according to the present invention in particular relates to a roll-to-plate imprinting process. The system benefits of the use of at least one connector which is configured to be attached to at least part of the substantially flexible stamp and at least part of the stage. The use of at least one connector according to the present invention results in that the flexible stamp the stage are mutually connected, via the connector, such that the relative position of the flexible stamp and the stage is substantially constant. Use of the connector according to the present invention results in that alignment between the flexible stamp and the stage is simplified before imprinting and during imprinting. This can be at least partially explained by the limited degree of freedom between the flexible stamp and the stage. Therefore use of the system according to the present invention will result in a more reproducible process. Hence, the imprinting process has a higher reproducibility resulting in more consistent and/or uniform products. This is enabled by the effective use of at least one connector which mutually connects the flexible stamp and the stage. The improved reproducibility can also be explained due to the system enabling that the substrate which is to be imprinted can be provided upon the stage the same way for subsequent imprinting processes. A further benefit of the use of a connector according to the present invention is that there is more controllability of the tension applied to the stamp during imprinting. Due to the flexible stamp being attached to the stage, displacement of the stage, in particular with respect to the roller, causes displacement of the flexible stamp too. Hence, the flexible stamp will also be displaced with respect to the roller. The system according to the invention is configured such that this will subsequently result in the flexible stamp being rolled over the substrate which is to be imprinted. Displacement of the stage with respect to the roller can for example be done in the inverse direction of the imprint direction. Alternatively, active displacement of the roller with respect to the stage, in particular in the imprint direction, will result in the roller exerting a pressure onto the flexible stamp and/or the substrate which is to be imprinted. The use of at least one connector enables a more accurate and stable imprinting process and also an improved repeatability. The imprinting step is facilitated in a relatively simple and effective manner by making use of a connector which mutually connects the stage and the flexible stamp. The system according to the invention enables a more efficient system in which the time required for the alignment can be reduced.

At least one flexible stamp can be directly and/or indirectly attached to at least one connector. It is beneficial if at least one flexible stamp is detachably connected to the connector. In this way, the system allows for replacement of the flexible stamp, for example on end of life of a flex stamp. It is for example imaginable that the flexible stamp comprises at least one frame, wherein said frame is connected to the connector. The use of at least one frame may increase the ease of replacement of at least one flexible stamp and the conformity and/or repeatability of resulting imprints made from a replacing flexible stamp. At least one connector can also be directly and/or indirectly attached to at least one stage. In a further possible embodiment, it is conceivable that at least one connector or at least part of at least one connector forms part of the stage. Hence, it is imaginable that at least one connector forms integral part of the stage. This results in a relatively solid and reliable configuration. Alternatively, it is imaginable that at least one connector, or at least part of at least one connector, forms (integral) part of the flexible stamp.

At least one roller and at least one stage are in particular mutually displaceable in an imprint direction, and/or the inverse thereof, in particular such that imprinting is facilitated. Typically, at least one roller and at least one stage are also displaceable in distance with respect to each other. It is for example imaginable that at least one roller and/or at least one stage are displaceable in vertical direction. It is imaginable that the mutual distance between at least one roller and at least one stage is adjustable. In a preferred embodiment, at least one stage is displaceable with respect to at least one roller. It is for example imaginable that at least one stage is displaceable in imprint direction and/or the inverse thereof, in particular such that imprinting is facilitated.

At least one roller is in particular configured for exerting pressure onto at least one flexible stamp and/or at least one substrate which is to be imprinted. It is also imaginable that at least one roller is configured for rolling at least one flexible stamp over at least one substrate which is to be imprinted. At least one roller is thereby typically configured for co-action with at least one flexible stamp which is configured for imprinting. The substantially flexible stamp can also be referred to as flexible substrate. Typically at least one substantially flexible stamp comprises at least one textured area. The textured area can for example comprise a texture with dimension in the range from 500 micrometer down to 25 nanometer. It is for example imaginable that at least a central part of the flexible stamp comprises a textured area. The flexible stamp is in particular configured for nano-imprint lithography transfer processes. However, it is also imaginable that at least one flexible stamp is substantially plain. This is for example beneficial in case the flexible stamp is applied for the transfer of objects. In a preferred embodiment, at least one substantially flexible stamp comprises at least two opposing edges. It is for example imaginable that at least one flexible stamp comprises two pairs of opposing edges, or side edges. In a beneficial embodiment, at least one substantially flexible stamp comprises at least two substantially rectilinear side edges. Such configuration will enable easy positioning and/or attaching of the flexible stamp. It is for example imaginable that at least one substantially flexible stamp is substantially rectangular and/or elongated. Typically, the length direction of the substantially rectangular or elongated flexible stamp is oriented in the imprint direction. It is for example possible that at least one connector is attached to a first edge of the substantially flexible stamp. It is for example possible that at least one distal end or distal edge of the flexible stamp is attached to the connector. Preferably, at least one connector has a width which at least equals the width of at least one substantially flexible stamp, and in particular at least one edge of the flexible stamp, and wherein at least one substantially flexible stamp is attached to the connector over the full width of at least one first edge of said substantially flexible stamp. Such embodiment is beneficial for the ease of alignment and for the ability to control the position of the flexible stamp during the imprinting process. A connector having a width which at least equals the width of the flexible stamp wherein the flexible stamp is attached and the connector are mutually connected over the full width of at least one first edge of the flexible stamp also enables that there is more controllability of the tension and/or pressure applied to the flexible stamp during imprinting. In yet a further embodiment, it is also imaginable that the system comprises at least separate connectors, or multiple connectors. It is possible that a single flexible stamp is connected to the stage via at least two connectors which are positioned at a distance from each other.

The connector connecting at least one flexible stamp and at least one stage can also be referred to as a primary connector. The system may additionally comprise at least one secondary connector which is attached at least one substantially flexible stamp at a distance from the primary connector. Preferably at least one secondary connector has a width which at least equals the width of at least one substantially flexible stamp, and at least one substantially flexible stamp is attached to the secondary connector over the full width of at least one second edge of said substantially flexible stamp. Preferably the second edge substantially opposes the first edge of the flexible stamp. It is for example imaginable that the primary connector is connected to a first distal edge or distal end of the flexible stamp and that the secondary connector is connected to a second distal edge or distal end of the flexible stamp. The secondary connector can be substantially stationary and/or displaceable. The secondary connector optionally be connected to at least part of the stage. It is for example conceivable that the system comprises at least one frame, wherein said frame is connected to at least one stage and to at least one secondary connector and/or at least one roller.

The system may comprise at least one primary actuator for adjusting the mutual position of at least one roller and at least one stage. Hence, at least one roller and at least one stage can be mutually displaceable by means of at least one primary actuator. The system, and in particular the actuator, may further comprise at least one drive unit. The primary actuator can be configured for adjusting the mutual distance between the stage and the roller and/or the mutual displacement in the imprint direction such that imprinting is facilitated.

In a preferred embodiment, the system according to the present invention comprises at least one carrier configured for carrying at least one substrate which is to be imprinted and wherein at least one stage is configured for providing support to at least one carrier and at least one substrate during imprinting. The at least one stage can be configured for providing support to at least one carrier and/or at least one substrate during imprinting. The use of a carrier can prevent that the substrate which is to be imprinted has to be placed directly upon the stage. It is preferred that at least part of at least one carrier is substantially situated between at least one roller and at least one stage, in particular at least in the imprinting position. Preferably, at least one carrier and at least one stage are mutually displaceable between at least an adjusting position, in particular wherein said carrier and said stage are positioned at a distance from each other and/or wherein said carrier and said stage are mutually displaceable in at least one direction which differs from the imprint direction such that at least one substrate provided upon said carrier can be aligned with respect to said stage, and an imprinting position, wherein at least one carrier engages at least one stage and/or is positioned directly upon at least one stage such that at least one substrate provided upon said carrier can be imprinted. The combination of at least one carrier which is configured for carrying at least one substrate which is to be imprinted and at least one stage configured for providing support to at least one carrier and/or at least one substrate during imprinting, wherein said carrier and said stage are mutually displaceable enables that alignment of the substrate is facilitated in a relatively simple and effective manner. This embodiment enables a more efficient system in which the time required for the alignment can be reduced and accuracy of alignment can be increased. Accurate alignment of the substrate with respect both the stage and the (flexible) stamp is very important in order to facilitate a high quality imprint. The combination of a stage and a carrier basically provides a two-layer surface which makes it possible to precisely align the substrate with respect to the stamp. The carrier further enables that direct engagement of the substrate can be prevented, in particular during loading of the substrate into the system, during alignment of the substrate within the system and/or during unloading of the imprinted substrate from the system. Typically, in prior art systems, the substrate, and it particular the edges thereof need to be touched, for example via clamps, for the (un)loading and/or alignment steps. However, touching of the substrate, and even the non-active areas thereof, can negatively affect the quality of the final product. Hence, this embodiment making use of at least one carrier allows for loading, unloading and alignment of the substrate without having to touch the edges of the substrate. This prevents deformations and defects of the substrate due to handling. At least one carrier, if applied, is in particular configured for carrying at least one substrate which is to be imprinted and has therefore as a main function to provide a stable base for the substrate to lay on. At least one carrier typically comprises at least one support surface for carrying at least one substrate. At least part of the carrier, in particular at least part of the support surface, may be substantially flat. A further function of the carrier is enabling movement of the substrate in at least one direction for aligning purposes. The carrier further provides for easy loading of substrate(s) into the system and for moving substrate(s) with respect to the roller and/or the flexible stamp. The function of the carrier can also be described as enables adjusting the position of the substrate in at least an y-direction and Rz direction. The direction of imprinting thereby equals the x-direction. In this way the carrier can align the substrate precisely in all directions without touching its edges.

It is imaginable that the system comprises at least one secondary actuator for adjusting the position of at least one carrier and/or at least one substrate with respect to at least one stage. The system may for example comprise at least one secondary actuator for adjusting the position of at least one carrier with respect to at least one stage. Adjusting the position of at least one carrier with respect to at least one stage via at least one secondary actuator is in particular possible at least in the adjusting position. The primary actuator and secondary actuator, if applied, are preferably independently controllable. At least one secondary actuator can also be configured for adjusting the position of at least one carrier with respect to at least one stage between the adjusting position and the imprinting position and/or for adjusting at least one carrier with respect to at least one stage into an aligned configuration in the adjusting position. It is also imaginable that at least one secondary actuator is configured for displacing at least one carrier with respect to at least one stage in at least one direction which differs from the imprint direction, in particular in the adjusting position. At least one primary actuator and/or at least one secondary actuator could for example be a DC motor, stepper motor, servo motor, voice coil actuator or linear actuator. Depending on the selected actuator a transmission can be used to achieve the required resolution, such as a gear box, planetary gear box, spindle, rocker mechanism or eccentric wheel.

At least one primary actuator and at least one secondary actuator are in particular independently controllable.

The system may also comprise at least one control unit for controlling the mutual displacement between at least one roller and at least one stage and/or between at least one carrier and at least one stage. At least one control unit can for example be configured to control the mutually displacement of at least one stage and at least one carrier between the adjusting position and the imprinting position. It is also conceivable that at least one control unit is configured to control alignment of the carrier with respect to the stage in the adjusting position.

In a further preferred embodiment, at least part of at least one carrier substantially encloses at least part of at least one stage, in particular at least in the imprinting position. It is for example imaginable that at least one carrier substantially encloses at least part of at least one stage in line with the imprint direction. Possibly, at least part of at least one carrier substantially encloses at least part of at least one stage in both the imprinting position and the adjusting position. In a further preferred embodiment, at least one carrier comprises at least one belt, in particular an endless belt. The use of at least one belt has several benefits. The (endless) belt enables easy alignment of the carrier, and thus of the substrate which is to be imprinted, in the adjusting position. The belt further enables that the system according to the present invention allows for loading, unloading and alignment of the substrate without having to touch the edges of the substrate in an effective manner. The substrate(s) can be provided onto the belt in a simple manner, wherein further displacement of the substrate can be achieved via the belt. At least one endless belt preferably encloses at least one stage. In a preferred embodiment, at least one endless belt encloses at least one stage such that the belt direction of the endless belt is substantially equal to or opposite of the imprint direction. Hence, the belt direction and imprint direction can both be in the x-direction. The belt direction should be interpreted as the travel direction of the belt. In case the system comprises a carrier comprising an endless belt, it is conceivable that said endless belt co-acts with at least two rollers, in particular guidance rollers. It is for example conceivable that the endless belt is attached around at least two rollers which are positioned at a distance from each other. It is also conceivable that at least one carrier comprises at least two rollers and at least one endless belt which is positioned over said rollers. The system may further comprise at least one housing, wherein at part of the housing is connected to the (guidance) rollers. The system may comprises at least one further actuator for actuating the belt.

It is possible that at least one carrier and/or at least one substrate provided upon at least one carrier can be coupled to at least one stage via air regulation, for example via vacuum or partial vacuum. In a further preferred embodiment, at least part of at least one carrier is permeable to air. Such embodiment could further enhance the efficiency of the overall imprinting process and the accuracy of the alignment. It is for example imaginable that fixation of at least one substrate on the carrier is achieved via an air flow and/or that the carrier is displaced towards the stage via an air flow. At least one carrier may for example comprise a plurality of air pockets, which can be configured to retain the substrate. In a further preferred embodiment, at least part of at least one carrier comprises a porous structure. At least part of the porous structure is preferably permeable to air. Preferably, at least part of least one carrier comprises a homogenous structure and/or a homogenous colour and/or a homogenous optical reflectivity and/or homogenous flatness and/or homogenous surface roughness and/or homogenous stiffness. In particular the area upon which the substrate is to be positioned should be substantially homogeneous. Differences in the structure and/or texture and/or colour and/or optical reflectivity of the carrier could negatively affect the overall imprinting process, since the substrate will be positioned upon the carrier during imprinting. At least part of at least one carrier may also comprise a web structure and/or mesh structure. It is for example conceivable that at least part of at least one carrier comprises a mesh, a raster, a matrix, a perforated structure and/or a woven structure. Hence, at least part of at least one carrier may comprise an at least partially open structure. It is for example imaginable that at least one carrier comprises cut outs, grooves and/or through holes. Such air-permeable structure can be beneficial in order to enable vacuum fixation of at least one substrate on the carrier. It is preferred that at least one carrier is substantially uniform in optical characteristics and/or mechanical characteristics. Hence, at least one carrier is preferably uniform in structure, colour, transparency, density, thickness and/or flexibility.

At least one carrier, if applied, is preferably relatively thin. This makes the carrier flexible and easy to handle. Preferably, at least one carrier has a thickness which is smaller than the thickness of at least one stage. It is also imaginable that at least part of at least one carrier is impermeable for air. For example at least part of the carrier which surrounds the part configured for carrying at least one substrate which is to be imprinted.

At least one stage is preferably substantially uniform in terms of flatness, surface roughness and/or local stiffness. At least one stage can for example comprise at least one mineral and/or ceramic material. Further non-limiting examples whereof at least one stage can be comprises are glass, granite, polymers, metal alloys, preferably aluminium or stainless steel. It is also imaginable that at least part of the stage comprises a conductive material.

In a preferred embodiment, at least one stage comprises at least one air channel. At least one air channel is in particular configured for the provision and/or intake of air. It is also conceivable that at least one stage comprises multiple air channels. The use of at least one air channel can provide for frictionless movement of the carrier with respect to the stage in particular via (compressed) air provided in the air channel(s). Hence, it is conceivable that the mutual displacement wherein at least one carrier and at least one stage are mutually displaced from the adjusting position to imprinting position is achieved via air provided in at least one air channel. Adjusting of the carrier with respect to the stage can also be facilitated and/or supported via air provided in at least one air channel. It is for example conceivable that a vacuum, partial vacuum or sub atmospheric pressure is applied to the air channel(s) such that the carrier, for example a carrier comprising a belt, will be (temporarily) fixated to the stage.

In an embodiment, the substrate to be imprinted may be a flexible sheet, for example a backing sheet of a flexible stamp or a blank flexible stamp. The flexible stamp comprised in the system may be a master stamp. The flexible substrate may after imprinted be used as a flexible stamp and may be comprised in the system, optionally after removing said master stamp from the system.

In an embodiment, the substrate comprised in the system may be provided with a texture or pattern prior to imprinting, or a master substrate. The flexible stamp comprised in the system may be a stamp without any texture or pattern, or a blank stamp. During imprinting, the master texture or pattern on said substrate or master substrate is transferred or imprinted onto the blank flexible stamp to form a texture or pattern on the flexible stamp. Optionally, said master substrate may be removed from the system, and a substrate to be imprinted may be loaded into the system to form a duplicate of the master texture or pattern after imprinting. In this way, the resulting imprinted texture or pattern may have an improved overlay with regard to the master substrate and accuracy of the duplication of the master texture or pattern is improved.

The system according to the invention may comprise at least one air pressure regulator configured for providing an air flow between at least one stage and at least one carrier. At least one air pressure regulator could for example be configured for providing an overpressure, a partial vacuum and/or a vacuum between at least one stage and at least one carrier. At least one air pressure regulator could also provide a flow of air in at least one air channel of the stage, if applied. By increasing pressure between the carrier and the stage, they can hoover with very little mutual friction. This is desirable when adjusting the mutual position of the carrier and the stage, and thus when aligning the substrate. When the desired position of the substrate is attained, the air pressure can be decreased, preferably below 1 atmosphere, to increase friction, and to make sure the carrier and the stage, and also the substrate provided upon the carrier are substantially fixated during imprinting. Additional to the friction between the carrier and the stage, it is desirable to also be able to decrease air pressure between the carrier and the substrate. In that way, unwanted displacement of the substrate laying on the carrier layer can be avoided. A conventional solution is to only rely on gravity. In order to be able to create a low air pressure between the carrier and the substrate, at the same time and using the same tools used for decreasing air pressure between the carrier and the stage, it is beneficial if air is able to move through the carrier.

In an optional embodiment, it is conceivable that the system comprises a heater and/or a cooler for heating and/or cooling at least part of the roller, in particular for heating and/or cooling at least part of the flexible stamp and/or for heating and/or cooling at least part of the substrate. Heating and/or cooling at least part of the roller could further optimize the imprinting process.

In a preferred embodiment, the system comprises at least two rollers. At least one roller, and preferably each roller is configured for exerting pressure onto at least one flexible stamp and/or at least one substrate which is to be imprinted. It is also imaginable that at least one roller, or each roller is configured for rolling at least one substantially flexible stamp over at least one substrate which is to be imprinted. The system may for example comprise a plurality of rollers for imprinting, transfer and/or delaminating purposes.

The system could possibly comprise at least one visual inspection device, for example but not limited to at least one camera. At least one visual inspection device can for example be configured to determine the location of at least one substrate which is to be imprinted. It is also conceivable that at least one visual inspection device is configured to determine the location of at least one flexible stamp and/or at least one stage. At least one control unit could be configured to control the mutual displacement between at least one roller and at least one stage, based upon the data obtained via the visual inspection means.

The system preferably comprises one or more sensors. It is for example imaginable that the system comprises at least one temperature sensor, tension sensor, pressure sensor, position sensor and/or combinations thereof. In a preferred embodiment, the system comprises at least one tension sensor for monitoring the tension in the substantially flexible stamp. At least one tension sensor can for example be configured to measure the dynamical tension in the flexible stamp during imprinting and/or to regulate the tension of the flexible stamp during imprinting. At least one sensor can for example comprise a load cell. At least one load cell can be configured to measure a force and/or tension in the substantially flexible stamp. The measuring and/or control of the tension in the substantially flexible stamp may further optimize the imprinting process. It is possible that at least one connector comprises at least one sensor and/or that at least one sensor forms part of the connector. It is also possible that at least one stage and/or at least one carrier, if applied, comprises at least one sensor and/or that at least one sensor forms part thereof.

At least one connector is preferably configured for co-action with different types of flexible stamps. At least one flexible stamp is preferably releasably attached to the connector. It is for example imaginable that at least one connector comprises at least one clamping element for clampingly connecting at least one flexible stamp. In this way, the substantially flexible stamp can be easily attached and/or removed and/or replaced in the exact same position, whilst the clamping element can provide sufficient strength to retain the flexible stamp within the system during the imprinting.

It is beneficial if at least one connector is at least partially adjustable. It is for example possible that at least one connector comprises at least one adjusting element configured for adjusting the position of at least one substantially flexible stamp with respect to at least one stage. In this way, the imprinting process can be more controlled and/or adapted to the stamp and/or substrate applied.

In a further embodiment of the system according to the present invention, it is imaginable that the stage is formed by the substrate which is to be imprinted. Hence, it is imaginable that the substrate which is to be imprinted forms integral part of the stage. As example part of the substrate can be clamped in the connector.

Within the context of this invention, imprinting could also be referred to as the transfer of a pattern. Hence, a pattern can be transferred from a substantially flexible stamp onto a substrate which is imprinting. The substrate which is to be imprinted can also be referred to as a receiving substrate.

Alternatively, the invention relates to a system for transferring at least one pattern, or texture, and/or at least one object, comprising:
at least one substantially flexible stamp configured for transferring at least one pattern or texture, and/or at least one object;
at least one roller configured for exerting pressure onto at least one substantially flexible stamp and/or at least one receiving substrate;
at least one stage configured for providing support to at least one receiving substrate during transfer;
   wherein at least one roller and at least one stage are mutually displaceable in at least an transfer direction in particular such that transfer of at least one pattern or texture, and/or at least one object onto at least one receiving surface is facilitated;
   and wherein the system comprises:
at least one connector which is attached to at least part of the substantially flexible stamp and at least part of the stage in particular such that the relative position of the flexible stamp and the stage is constant.

The system can be combined with any of the described embodiment related to the present invention. The transfer of at least one object, or multiple objects, can for example enable transfers of object(s) to from a donor substrate to a receiving substrate. Non-limiting examples of possible objects which can be transferred within the context of this invention are micro elements, microprocessors and/or micro-LEDs. The system according to the invention in particular relates to a transfer process making use of roll-to-plate transfer.

The invention further relates to an assembly for imprinting, in particular nanoimprinting, comprising at least one roller configured for co-action with at least one flexible stamp, and said roller in particular being configured for exerting pressure onto at least one substantially flexible stamp and/or at least one substrate which is to be imprinted, at least one stage configured for providing support to at least one substrate during imprinting, wherein at least one roller and at least one stage are mutually displaceable in at least an imprint direction in particular such that imprinting is facilitated and wherein the system comprises at least one connector which is configured to be attached to at least part of the substantially flexible stamp and/or to at least part of the stage.

The invention also relates to a process for imprinting, in particular nanoimprinting, making use of at least one system according to the present invention, wherein the process comprises the steps of providing at least one substrate which is to be imprinted directly or indirectly upon at least one stage and imprinting of the substrate via exerting a pressure onto at least one flexible stamp and/or at least one substrate which is to be imprinted. The process according to the invention is also directed to a process for transferring at least one pattern or texture and/or at least one object, making use of at least one system according to the present invention, wherein the process comprises the steps of providing at least one receiving substrate directly or indirectly upon at least one stage and transfer of at least one pattern, or texture, and/or at least one object onto the receiving substrate via exerting a pressure onto at least one flexible stamp and/or at least one receiving substrate

The process according to the present invention has similar benefits as described for the system according to the present invention. The process can be used in combination with any of the described embodiments of the system according to the present invention. In case at least one carrier is applied, at least one substrate which is to be imprinted can be positioned upon said carrier. The process may further comprise the step of attaching at least one connector to at least part of the substantially flexible stamp and/or to at least part of the stage. In a preferred embodiment, the process comprises the step of attaching at least part of at least one flexible stamp to at least one connector. It is imaginable that the type of flexible stamp applied depends on the desired imprinting, or transfer, process. Hence, it is imaginable that at least one flexible stamp is to be changed or replaced before or after use. The connector can be configured to enable replacement of the flexible stamp in an effective, reliable and efficient manner. The method according to the present invention can for example comprise the (subsequent) steps of providing at least one substrate which is to be imprinted upon at least one stage, attaching at least one flexible stamp to the stage via at least one connector and performing at least one imprinting step via exerting a pressure onto at least one flexible stamp and/or at least one substrate which is to be imprinted via at least one roller. The method may also comprise the steps of removing the imprinted substrate from the stage and/or removing the flexible stamp from the connector and/or replacing the flexible stamp. The process may further comprise the step of aligning the mutual position of at least one carrier and at least one stage such that the substrate is substantially aligned at least with respect to at least one stage and bringing at least one carrier and at least one stage into an imprinting position, wherein at least one carrier is positioned directly upon at least one stage such that the substrate provided upon at least one carrier can be imprinted.

The invention will be further elucidated by means of the following non-limitative clauses.

1. System for imprinting, in particular nanoimprinting, comprising:
at least one substantially flexible stamp configured for imprinting, in particular nanoimprinting;
at least one roller configured for exerting pressure onto at least one substantially flexible stamp and/or at least one substrate which is to be imprinted;
at least one stage configured for providing support to at least one substrate during imprinting;
   wherein at least one roller and at least one stage are mutually displaceable in at least an imprint direction in particular such that imprinting is facilitated;
   and wherein the system comprises:
at least one connector which is attached or attachable to at least part of the substantially flexible stamp and to at least part of the stage.

2. System according to clause 1, wherein at least one substantially flexible stamp comprises at least one textured area.

3. System according to any of the previous clauses, wherein at least one substantially flexible stamp comprises at least two opposing side edges, preferably at least two substantially rectilinear side edges.

4. System according to any of the previous clauses, wherein at least one connector is attached to a first edge of the substantially flexible stamp.

5. System according to any of the previous clauses, wherein at least one connector has a width which at least equals the width of at least one substantially flexible stamp, and wherein at least one substantially flexible stamp is attached to the connector over the full width of at least one first edge of said substantially flexible stamp.

6. System according to any of the previous clauses, wherein at least one connector forms part of the stage.

7. System according to any of the previous clauses, comprising at least one secondary connector which is attached at least one substantially flexible stamp at a distance from the connector which connects at least part of the substantially flexible stamp and at least part of the stage.

8. System according to clause 7, wherein at least one secondary connector has a width which at least equals the width of at least one substantially flexible stamp, and wherein at least one substantially flexible stamp is attached to the secondary connector over the full width of at least one second edge of said substantially flexible stamp.

9. System according to any of the previous clauses, comprising at least one primary actuator for adjusting the mutual position of at least one roller and at least one stage.

10 System according to any of the previous clauses, comprising at least one carrier configured for carrying at least one substrate which is to be imprinted and wherein at least one stage is configured for providing support to at least one carrier and at least one substrate during imprinting, preferably wherein at least part of at least one carrier is substantially situated between at least one roller and at least one stage.

11. System according to clause 10, wherein at least one carrier and at least one stage are mutually displaceable between at least:
an adjusting position, wherein said carrier and said stage are mutually displaceable in at least one direction which differs from the imprint direction such that at least one substrate provided upon said carrier can be aligned with respect to said stage; and
an imprinting position, wherein at least one carrier is positioned such that at least one substrate provided upon said carrier can be imprinted.

12. System according to clause 10 or clause 11, comprising at least one secondary actuator for adjusting the position of at least one carrier with respect to at least one stage.

13 System according to any of the previous clauses, wherein at least one stage comprises at least one air channel for the provision and/or intake of air.

14. System according to any of the previous clauses, comprising at least one heater for heating and/or cooling of at least part of the roller.

15. System according to any of the previous clauses, comprising at least one visual inspection device.

16 System according to any of the previous clauses, comprising at least one tension sensor for monitoring the tension in the substantially flexible stamp.

17. System according to any of the previous clauses, wherein at least one connector comprises at least one clamping element for clampingly connecting at least one flexible stamp.

18. System according to any of the previous clauses, wherein at least one connector comprises at least one adjusting element configured for adjusting the position of at least one substantially flexible stamp with respect to at least one stage.

19 Process for imprinting, in particular nanoimprinting, making use of at least one system according to any of the previous clauses, comprising the steps of providing at least one substrate which is to be imprinted directly or indirectly upon at least one stage and imprinting of the substrate via exerting a pressure onto at least one flexible stamp and/or at least one substrate which is to be imprinted.

20. Process according to clause 19, comprising the step of attaching at least one connector to at least part of the substantially flexible stamp and/or to at least part of the stage.

21. Process according to clause 19 or 20, comprising the step of attaching at least part of at least one flexible stamp to at least one connector.

### BRIEF DESCRIPTION OF THE DRAWINGS

The terms Fig., Figs., Figure, and Figures are used interchangeably in the specification to refer to the corresponding figures in the drawings.

The invention will be further elucidated by means of non-limiting exemplary embodiments illustrated in the following figures, in which:

FIGS. 1a and 1b show a possible embodiment of a system for imprinting according to the present invention.

Within these figures, similar reference numbers correspond to similar or equivalent elements or features.

### DESCRIPTION OF THE INVENTION

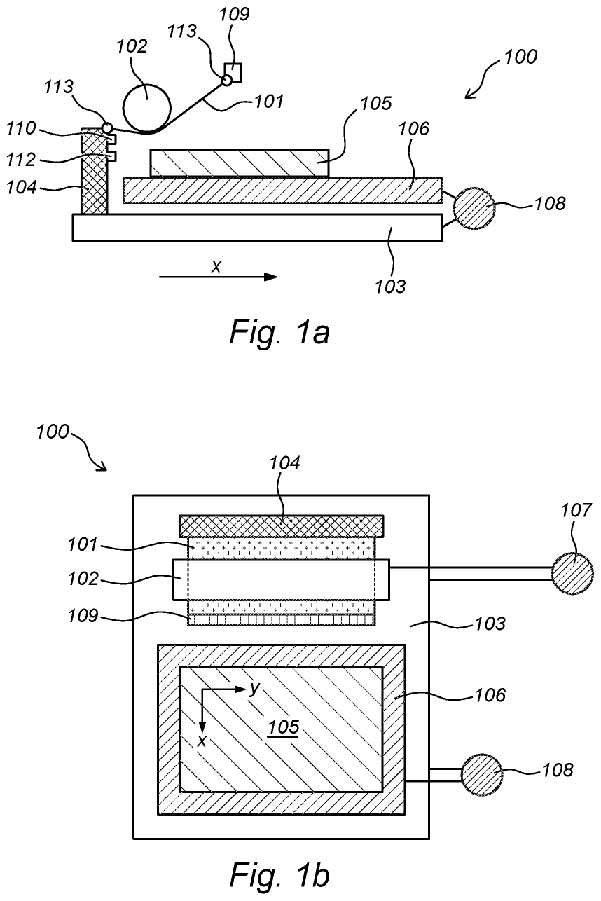

FIGS. 1a and 1b show a schematic representation of system 100 for imprinting, in particular nanoimprinting, according to the present invention. FIG. 1a shows a side view where FIG. 1b shows a top view. The system 100 comprises a substantially flexible stamp 101 configured for imprinting, in particular nanoimprinting. The system 100 further comprises a roller 102 configured for rolling the flexible stamp 101 over a substrate 105 which is to be imprinted and a stage 103 configured for providing support to the substrate 105 during imprinting. The roller 102 and the stage 103 are mutually displaceable in an imprint direction (x-direction) such that imprinting is facilitated. The system 100 further comprises a connector 104 which is attached to part of the flexible stamp 101 and part of the stage 103. In the shown embodiment, the system 100 further comprises a carrier 106 configured for carrying the substrate 105 which is to be imprinted. Hence, in the shown embodiment the stage 103 is also configured for providing support to said carrier 106 during imprinting. The carrier 106 is substantially situated between the roller 102 and the stage 103, at least in the imprinting position. The carrier 106 and the stage 103 are mutually displaceable between at least an adjusting position, wherein the carrier 106 and the stage 103 are positioned at a distance from each other and wherein said carrier 106 and said stage 103 are mutually displaceable in at least one direction which differs from the imprint direction such that the substrate 105 provided upon the carrier 106 can be aligned with respect to the stage 103 and an imprinting position, wherein the carrier 106 is positioned directly upon the stage 103 such that the substrate 105 provided upon the carrier 106 can be imprinted. In the shown schematic figures, the carrier 106 and the stage 103 are in an adjusting position. The system 100 comprises a primary actuator 107 for adjusting the mutual position of the roller 102 and the stage 103 and a secondary actuator 108 for adjusting the position of the carrier 106 with respect to the stage 103. In the shown embodiment, the flexible stamp 101 is substantially rectangular and the connector 104 is attached to a first edge of the flexible stamp 101. The connector 104 has a width which substantially equals the width of the flexible stamp 101. The flexible stamp 101 is attached to the connector 104 over substantially the full width of a first edge thereof. A further side of the flexible stamp 101 is attached to a secondary connector 109. It is imaginable that the connectors 104, 109 comprise at least one clamping element 113. The (primary) connector 104 comprises an adjusting element 110 configured for adjusting the position of the flexible stamp 101 with respect to the stage 104. The system 100 also comprises a sensor 112, in particular a tension sensor 112 for monitoring the tension in the substantially flexible stamp 101.

It will be clear that the invention is not limited to the exemplary embodiments which are illustrated and described here, but that countless variants are possible within the framework of the attached claims, which will be obvious to the person skilled in the art. In this case, it is conceivable for different inventive concepts and/or technical measures of the above-described variant embodiments to be completely or partly combined without departing from the inventive idea described in the attached claims.

The verb ‘comprise’ and its conjugations as used in this patent document are understood to mean not only ‘comprise’, but to also include the expressions ‘contain’, ‘substantially contain’, ‘formed by’ and conjugations thereof.

1. A system for imprinting or nanoimprinting, comprising:
at least one substantially flexible stamp configured for imprinting, in particular or nanoimprinting;
at least one roller configured for exerting pressure onto the at least one substantially flexible stamp and/or at least one substrate which is to be imprinted;
at least one carrier configured for carrying the at least one substrate which is to be imprinted
at least one stage configured for providing support to the at least one carrier and/or the at least one substrate during imprinting;
wherein the at least one roller and the at least one stage are mutually displaceable in at least an imprint direction such that imprinting is facilitated;
and wherein the system comprises:
at least one connector which is attached or attachable to at least part of the substantially flexible stamp and to at least part of the stage; and
wherein at least part of the at least one carrier is situated between the at least one roller and the at least one stage, and wherein the at least one carrier and the at least one stage are mutually displaceable between at least:
an adjusting position, wherein said carrier and said stage are mutually displaceable in at least one direction which differs from the imprint direction such that the at least one substrate provided upon said carrier can be aligned with respect to said stage; and
an imprinting position, wherein the at least one carrier is positioned such that the at least one substrate provided upon said carrier can be imprinted.

2. The system according to claim 1, wherein the at least one substantially flexible stamp comprises at least one textured area.

3. The system according to claim 1, wherein the at least one substantially flexible stamp comprises at least two opposing side edges.

4. The system according to claim 3, wherein the at least one connector is attached to a first edge of the substantially flexible stamp.

5. The system according to claim 1, wherein the at least one connector has a width which at least equals the width of the at least one substantially flexible stamp, and wherein the at least one substantially flexible stamp is attached to the connector over the full width of at least one first edge of said substantially flexible stamp.

6. The system according to claim 1, wherein the at least one connector forms part of the stage.

7. The system according to claim 1, comprising at least one secondary connector which is attached the at least one substantially flexible stamp at a distance from the connector which connects at least part of the substantially flexible stamp and at least part of the stage.

8. The system according to claim 7, wherein the at least one secondary connector has a width which at least equals the width of the at least one substantially flexible stamp, and wherein the at least one substantially flexible stamp is attached to the secondary connector over the full width of at least one second edge of said substantially flexible stamp.

9. The system according to claim 1, comprising at least one primary actuator for adjusting the mutual position of the at least one roller and the at least one stage.

10. The system according to claim 1, wherein at least part of the at least one carrier substantially encloses at least part of the at least one stage.

11. The system according to claim 1, wherein the at least one carrier comprises at least one endless belt which is attached around at least two guidance rollers which are positioned at a distance from each other.

12. The system according to claim 1, comprising at least one secondary actuator for adjusting the position of the at least one carrier with respect to the at least one stage.

13. The system according to claim 1, wherein the at least one stage comprises at least one air channel for the provision and/or intake of air.

14. The system according to claim 1, comprising at least one heater for heating and/or cooling of at least part of the roller.

15. The system according to claim 1, comprising at least one visual inspection device.

16. The system according to claim 1, comprising at least one tension sensor for monitoring the tension in the substantially flexible stamp.

17. The system according to claim 1, wherein the at least one connector comprises at least one clamping element for clampingly connecting the at least one flexible stamp.

18. The system according to claim 1, wherein the at least one connector comprises at least one adjusting element configured for adjusting the position of the at least one substantially flexible stamp with respect to the at least one stage.

19. A process for imprinting or nanoimprinting, making use of at least one system according to claim 1, comprising the steps of providing at least one substrate which is to be imprinted directly or indirectly upon at least one stage and imprinting of the at least one substrate via exerting a pressure onto at least one flexible stamp and/or the at least one substrate which is to be imprinted.

20. The process according to claim 19, comprising the step of attaching at least one connector to at least part of the substantially flexible stamp and/or to at least part of the stage and/or comprising the step of attaching at least part of the at least one flexible stamp to at least one connector.

21. (canceled)
